(19) United States
(12) Patent Application Publication
(10) Pub. No.: US 2015/0063595 A1
(43) Pub. Date: Mar. 5, 2015

(54) SPEAKER APPARATUS

(71) Applicant: NOKIA CORPORATION, Espoo (FI)

(72) Inventors: Pasi Tuomo Antero KEMPPINEN, TAMPERE (FI); Mikko Tapio JYRKINEN, Tampere (FI)

(21) Appl. No.: 14/464,470

(22) Filed: Aug. 20, 2014

(30) Foreign Application Priority Data
Aug. 29, 2013 (GB) 1315378.8

(51) Int. Cl. H04R 17/00; H04R 1/28; H04R 9/06; H03G 5/16

(52) U.S. Cl. CPC H04R 17/00; H03G 5/16; H04R 1/2803; H04R 9/06; H04R 2217/01; H04R 2400/03
USPC 381/101; 381/151

(57) ABSTRACT

An apparatus comprising: a surface; at least one contact transducer, wherein the at least one contact transducer is coupled to the surface and configured to move the surface to generate at least one acoustic signal, wherein the at least one acoustic signal is configured to be transmitted at least by the surface; at least one acoustic enhancer configured to enhance the acoustic output of the at least one contact transducer, wherein the at least one acoustic enhancer comprises at least one further transducer configured to generate at least one further acoustic signal.

### FIELD OF THE APPLICATION

The present application relates to a method for generating acoustic signals and speaker apparatus configured to generate acoustic signals. In some embodiments the method for generating acoustic signals and speaker apparatus configured to generate acoustic signals relate to mobile apparatus methods for generating acoustic signals and mobile apparatus speaker apparatus configured to generate acoustic signals.

### BACKGROUND OF THE APPLICATION

Many portable devices, for example mobile telephones, are equipped with a display such as a glass or plastic display window for providing information to the user. Furthermore such display windows are now commonly used as touch sensitive inputs. In some cases the apparatus can provide a visual feedback and audible feedback when recording a touch input. In some further devices the audible feedback is augmented with a vibrating motor used to provide a haptic feedback so the user knows that the device has accepted the input.

Furthermore such devices typically also use electro-acoustic transducers to produce audio for earpiece and integrated hands free (IHF) operations as well as for alert tones. The moving coil dynamic speaker configuration used is typically relatively large in relation to the volume within the device and require specific signal processing considerations in order that the acoustic frequency response is acceptable. Furthermore moving coil transducers to produce an acoustic signal from the front of the device, in order to produce sound which comes from the front surface of the apparatus, typically uses a device design with an audio outlet on the front surface. In the following description the terms acoustic signal, or acoustic wave, or acoustic sound are considered to define an acoustic output of the form which can be within or cover the auditory frequency range. In other words the terms can be understood to define air pressure variations which can be heard or experienced in other ways such as felt by the user.

Current design principles for portable devices are to cover the front surface with as much display or front window as possible so to produce a device with as big a display area and without wasted bezel areas or regions about the display increasing the overall size of the device and making it unwieldy.

However to produce an acoustic wave from the front of the device with at least one audio outlet is difficult to produce and can lead to the display being structurally weakened in the region of the audio outlets. Furthermore these outlets can attract contaminants such as small iron particles. These contaminants can cause distortion and faults within the transducers significantly reducing the lifetime of the device.

### SUMMARY OF SOME EMBODIMENTS

In a first aspect of the application there is provided an apparatus comprising a surface; at least one contact transducer, wherein the at least one contact transducer is coupled to the surface and configured to move the surface to generate at least one acoustic signal wherein the at least one acoustic signal is configured to be transmitted at least by the surface; and at least one acoustic enhancer configured to enhance the acoustic output of the at least one contact transducer wherein the at least one acoustic enhancer comprises at least one further transducer configured to generate at least one further acoustic signal.

The at least one further transducer configured to generate at least one further acoustic signal may generate the at least one further acoustic signal by moving the surface, such that the at least one further acoustic signal enhances the frequency response of the acoustic output of the at least one contact transducer.

The at least one further transducer may be configured to generate the at least one further acoustic signal towards an acoustic volume at least partially defined by one side of the at least one further transducer.

The acoustic volume may be further defined at least by the surface.

The apparatus may further comprise a further acoustic volume at least partially defined by the other side of the at least one further transducer and at least one acoustic port wherein the at least one further transducer may be configured to output at least one additional acoustic signal via the further acoustic volume and the at least one acoustic port.

The further acoustic volume may be further defined at least by a casing of the apparatus.

The at least one acoustic port may be located within the casing of the apparatus, and wherein the at least one additional acoustic signal may be configured to be transmitted from the apparatus by passing through the at least one acoustic port.

The at least one further transducer may comprise at least one of: at least one integrated hands free speaker; at least one moving coil speaker; at least one multi-function device; and at least one piezo-electric transducer.

The at least one contact transducer may comprise at least one of: at least one piezoelectric actuator coupled to the surface and configured to bend the surface along the length of the coupling to generate the at least one acoustic signal; at least one piezoelectric actuator coupled at a first region to the surface and coupled at a second region to at least one anchor point and configured to move the surface relative to the anchor point to generate the at least one acoustic signal; at least one piezoelectric actuator coupled to a pad, the pad coupled to the surface at a first point and the actuator is further coupled to at least one anchor point at a second point and configured to move the surface via the pad relative to the anchor point to generate the at least one acoustic signal; at least one first piezoelectric actuator coupled to the surface along a first region and at least one further piezoelectric actuator coupled to the surface along a second region, the first and second regions being located approximately at opposite ends of the surface and configured to bend the surface along the length of the coupling to generate the at least one acoustic signal; at least one first piezoelectric actuator coupled at a first region to a first location of the surface and coupled at a second region to at least one first anchor point and at least one further piezoelectric actuator coupled at a first region to a further location of the surface and coupled at a second region to at least one further anchor point, wherein the first and second piezoelectric actuators are located approximately at opposite ends of the surface and the at least one first piezoelectric actuator and the at least one further piezoelectric actuator is configured to move the surface relative to the first and further anchor point respectively to generate the at least one acoustic signal; and at least one first piezoelectric actuator coupled to a first pad, the first pad coupled to the surface at a first location and the at least one first piezoelectric actuator is further coupled to at least one anchor point and at least one further piezoelectric actuator coupled to a further pad, the further pad coupled to the surface at a further location, and the at least one further piezoelectric actuator is further coupled to at least one further anchor point, wherein the first location and the further location being approximately at opposite ends of the surface and the at least one first piezoelectric actuator and at least one further piezoelectric actuator being configured to move the surface via the first and further pad respectively to generate the at least one acoustic signal.

The apparatus may further comprise: at least one audio signal generator configured to generate at least one audio signal to be output by the at least one contact transducer and the at least one further transducer; at least one low pass filter configured to filter the output of the at least one audio signal generator and coupled to the at least one further transducer to generate lower frequency acoustic signals; and at least one high pass filter configured to filter the output of the at least one audio signal generator and coupled to the at least one contact transducer to generate higher frequency acoustic signals.

The apparatus may further comprise at least one audio signal generator configured to generate at least one audio signal to be output by the at least one further transducer only, when the apparatus is operating in a handsfree mode.

The at least one acoustic enhancer may further comprise at least one micro-hole through the surface, wherein the at least one micro-hole is configured to operate as an acoustic window such that the acoustic signal and further acoustic signal can pass through the acoustic window and enhance the frequency response of the acoustic output of the at least one contact transducer.

The at least one contact transducer may comprise at least one of: at least one piezoelectric actuator; at least one vibra; and at least one actuator configured to move the surface.

The surface may comprise at least one of: an apparatus display module; an apparatus front window; and an apparatus casing.

According to a second aspect there is provided a method comprising: providing a surface; coupling at least one contact transducer to the surface such that the at least one contact transducer moves the surface to generate at least one acoustic signal; providing at least one acoustic enhancer to enhance the acoustic output of the at least one contact transducer, wherein providing the at least one acoustic enhancer comprises providing at least one further transducer to generate at least one further acoustic signal.

Providing at least one further transducer may comprise generating the at least one acoustic signal by moving the surface, such that the at least one further acoustic signal enhances the frequency response of the at least one contact transducer.

The method may comprise generating the at least one further acoustic signal towards an acoustic volume at least partially defined by one side of the at least one further transducer.

The acoustic volume may be further defined at least by the surface.

The method may further comprise providing a further acoustic volume at least partially defined by the other side of the at least one further transducer and at least one acoustic port and outputting at least one additional acoustic signal from the at least one further transducer towards the further acoustic volume and the at least one acoustic port.

The further acoustic volume may be further defined at least by a casing of the apparatus.

The method may comprise locating the at least one acoustic port within the casing of the apparatus, and transmitting the at least one additional acoustic signal from the apparatus by passing through the at least one acoustic port.

Providing the at least one contact transducer may comprise at least one of: providing at least one piezoelectric actuator coupled to the surface and configured to bend the surface along the length of the coupling to generate the at least one acoustic signal; providing at least one piezoelectric actuator coupled at a first region to the surface and coupled at a second region to at least one anchor point and configured to move the surface relative to the anchor point to generate the at least one acoustic signal; providing at least one piezoelectric actuator coupled to a pad, the pad coupled to the surface at a first point and the actuator is further coupled to at least one anchor point at a second point and configured to move the surface via the pad relative to the anchor point to generate the at least one acoustic signal; providing at least one first piezoelectric actuator coupled to the surface along a first region and at least one further piezoelectric actuator coupled to the surface along a second region, the first and second regions being located approximately at opposite ends of the surface and configured to bend the surface along the length of the coupling to generate the at least one acoustic signal; providing at least one first piezoelectric actuator coupled at a first region to a first location of the surface and coupled at a second region to at least one first anchor point and at least one further piezoelectric actuator coupled at a first region to a further location of the surface and coupled at a second region to at least one further anchor point, wherein the first and second piezoelectric actuators are located approximately at opposite ends of the surface and the at least one first piezoelectric actuator and the at least one further piezoelectric actuator is configured to move the surface relative to the first and further anchor point respectively to generate the at least one acoustic signal; and providing at least one first piezoelectric actuator coupled to a first pad, the first pad coupled to the surface at a first location and the at least one first piezoelectric actuator is further coupled to at least one anchor point and at least one further piezoelectric actuator coupled to a further pad, the further pad coupled to the surface at a further location, and the at least one further piezoelectric actuator is further coupled to at least one further anchor point, wherein the first location and the further location being approximately at opposite ends of the surface and the at least one first piezoelectric actuator and at least one further piezoelectric actuator being configured to move the surface via the first and further pad respectively to generate the at least one acoustic signal.

The method may further comprise: providing at least one audio signal generator to generate at least one audio signal to be output by the at least one contact transducer and the at least one further transducer; providing at least one low pass filter to filter the output of the at least one audio signal generator and coupled to the at least one further transducer to generate lower frequency acoustic signals; and providing at least one high pass filter to filter the output of the at least one audio signal generator and coupled to the at least one contact transducer to generate higher frequency acoustic signals.

The method may further comprise providing at least one audio signal generator to generate at least one audio signal to be output by the at least one further transducer only, when the apparatus is operating in a handsfree mode.

Providing at least one acoustic enhancer to enhance the frequency response of the at least one transducer may further comprise: providing at least one micro-hole through the surface, wherein the at least one micro-hole is configured to operate as an acoustic window such that the acoustic signal and further acoustic signal can pass through the acoustic window and enhance the frequency response of the at least one contact transducer.

Providing the surface may comprise providing at least one of: an apparatus display module; an apparatus front window; and an apparatus casing.

According to a third aspect there is provided an apparatus comprising: a surface means; at least one contact transducer means coupled to the surface means and for generating at least one acoustic signal by moving the surface means; at least one enhancer means for enhancing the acoustic output of the at least one contact transducer means, wherein the at least one enhancer means may comprise at least one further transducer means for generating at least one further acoustic signal.

The at least one further transducer means for generating at least one further acoustic signal may generate the at least one further acoustic signal by moving the surface, such that the at least one further acoustic signal enhances the frequency response of the at least one contact transducer means.

The at least one further transducer means may generate the at least one further acoustic signal towards an acoustic volume at least partially defined by one side of the at least one further transducer means.

The acoustic volume may be further defined at least by the surface means.

The apparatus may further comprise a further acoustic volume at least partially defined by the other side of the at least one further transducer means and at least one acoustic port means wherein the at least one further transducer means may be configured to output at least one additional acoustic signal via the further acoustic volume and the at least one acoustic port means.

The further acoustic volume may be further defined at least by a casing means of the apparatus.

The at least one acoustic port means may be located within the casing means, and wherein the at least one additional acoustic signal may be configured to be transmitted from the apparatus by passing through the at least one acoustic port means.

The at least one further transducer means may comprise at least one of: at least one integrated hands free speaker; at least one moving coil speaker; at least one multi-function device; and at least one piezo-electric transducer.

The at least one contact transducer means may comprise at least one of: at least one piezoelectric actuator coupled to the surface and configured to bend the surface along the length of the coupling to generate the at least one acoustic signal; at least one piezoelectric actuator coupled at a first region to the surface and coupled at a second region to at least one anchor point and configured to move the surface relative to the anchor point to generate the at least one acoustic signal; at least one piezoelectric actuator coupled to a pad, the pad coupled to the surface at a first point and the actuator is further coupled to at least one anchor point at a second point and configured to move the surface via the pad relative to the anchor point to generate the at least one acoustic signal; at least one first piezoelectric actuator coupled to the surface along a first region and at least one further piezoelectric actuator coupled to the surface along a second region, the first and second regions being located approximately at opposite ends of the surface and configured to bend the surface along the length of the coupling to generate the at least one acoustic signal; at least one first piezoelectric actuator coupled at a first region to a first location of the surface and coupled at a second region to at least one first anchor point and at least one further piezoelectric actuator coupled at a first region to a further location of the surface and coupled at a second region to at least one further anchor point, wherein the first and second piezoelectric actuators are located approximately at opposite ends of the surface and the at least one first piezoelectric actuator and the at least one further piezoelectric actuator is configured to move the surface relative to the first and further anchor point respectively to generate the at least one acoustic signal; and at least one first piezoelectric actuator coupled to a first pad, the first pad coupled to the surface at a first location and the at least one first piezoelectric actuator is further coupled to at least one anchor point and at least one further piezoelectric actuator coupled to a further pad, the further pad coupled to the surface at a further location, and the at least one further piezoelectric actuator is further coupled to at least one further anchor point, wherein the first location and the further location being approximately at opposite ends of the surface and the at least one first piezoelectric actuator and at least one further piezoelectric actuator being configured to move the surface via the first and further pad respectively to generate the at least one acoustic signal.

The apparatus may further comprise: at least one audio signal generator means configured to generate at least one audio signal to be output by the at least one contact transducer means and the at least one further transducer means; at least one low pass filtering means configured to filter the output of the at least one audio signal generator means and coupled to the at least one further transducer means to generate lower frequency acoustic signals; and at least one high pass filter means configured to filter the output of the at least one audio signal generator means and coupled to the at least one contact transducer means to generate higher frequency acoustic signals.

The apparatus may further comprise means for generating at least one audio signal to be output by the at least one further transducer means only, when the apparatus is operating in a handsfree mode.

The at least one enhancer means may further comprise: at least one micro-hole through the surface, wherein the at least one micro-hole is configured to operate as an acoustic window such that the acoustic signal and further acoustic signal can pass through the acoustic window and enhance the frequency response of the at least one contact transducer.

The at least one contact transducer means may comprise at least one of: at least one piezoelectric actuator; at least one vibra; and at least one actuator configured to move the surface.

The surface means may comprise at least one of: an apparatus display module; an apparatus front window; and an apparatus casing.

An electronic device may comprise an apparatus as described above.

Embodiments of the present invention aim to address one or more of the above problems.

### BRIEF DESCRIPTION OF DRAWINGS

For a better understanding of the present application and as to how the same may be carried into effect, reference will now be made by way of example to the accompanying drawings in which:

FIG. 1 illustrates a schematic block diagram of an apparatus according to some embodiments;

FIG. 2 illustrates a schematic isometric projection and sectioned projection of a first apparatus employing some embodiments;

FIG. 3 illustrates a schematic isometric projection and sectioned projection of a second apparatus employing some embodiments;

FIG. 4 illustrates a schematic isometric projection and sectioned projection of a further apparatus employing some embodiments;

FIG. 5 illustrates a schematic sectioned projection of an additional apparatus employing some embodiments;

FIG. 6 illustrates a schematic sectioned projection of an apparatus comprising a further contact actuator configuration according to some embodiments; and

FIGS. 7 and 8 illustrate graphical representations of the audio frequency responses of some embodiments.

### SOME EMBODIMENTS OF THE APPLICATION

The application describes apparatus and methods of construction for speaker apparatus or module suitable for providing a surface vibrating speaker suitable for being implemented within a portable or mobile device. Although the following examples demonstrate the apparatus and methods of construction for speaker apparatus or module suitable for providing a surface vibrating speaker implemented within a portable or mobile device it would be understood that similar structures can be implemented in some embodiments within static, fixed or semi-portable devices. Furthermore although the following examples define the surface as being a display surface, it would be understood that the surface can be any suitable surface of the apparatus. For example in some embodiments the surface could be a first portion of a casing or cover of the apparatus against which the contact actuator as described herein is placed or located. In such embodiments a first acoustic volume can be defined by the first portion of the casing or cover (for example a ‘front’ portion of the casing and cover where the user is likely to place their ear) and an air mass actuator. In some such embodiments a further acoustic volume can be defined by a further portion of the casing or cover (for example a ‘rear’ or ‘side’ portion of the casing and cover where a window permits the acoustic waves to pass through) and the other side of the air mass actuator.

As discussed herein a problem in modern electrical apparatus or device design is one where the size of the screen of the device is maximised with respect to the size of the ‘front’ face of the device whilst being able to generate a sound from the ‘front’ face of the device. Often the compromise is one where the ‘front’ face of the device has sound or acoustic outlets to at least one side of the display making the device larger than strictly required by the display size. For example the mobile phone model HTC one has two strips of sound outlets on each of the narrow sides of the screen to produce ‘front’ or forward audio.

One approach which has been attempted is to vibrate the surface such that when located in typical handset mode near the ear the vibration is conducted to the ear, in a manner similar to bone conduction. However such devices are typically unable to produce good quality wideband audio output, for example an example conduction device the Kyocera's Urbano Expresso produces a frequency output response which would not be sufficient to obtain a CE mark.

The concept as described herein with respect to the embodiments shown is to enhance the audio performance of a transducer located behind the display or surface.

A first series of embodiments which enhance the audio performance of the transducer is to employ a transducer or actuator which is coupled either directly or indirectly to the display, display window, or surface to physically vibrate the surface (or display or display window) and a conventional transducer or actuator configured to vibrate the surface or display or display window at the lower frequencies which enhance the audio performance and attempt to improve the frequency response of the audio output generated by the mechanically coupled transducer. In other words to use both contact (or mechanically actuated) vibration (for example generated by a vibra or piezo-electric actuator coupled either directly or via a pad to the surface, display or front window) and a conventional transducer, such as multifunction device vibra, or air mass surface vibration for example generated by an integrated hands free (IHF) speaker configured to vibrate the surface, display, or display window. Combining both vibrations the surface (display or display window) is enabled to generate suitable acoustic waves over a suitable range of frequencies. In the examples and embodiments described herein the contact transducer or contact actuator is mechanically coupled either directly or indirectly to a display or display module or display module component such as a front window. However it would be appreciated that in embodiments any suitable surface can be actuated in a similar manner. For example a ‘front’ surface of a display-less device (in other words a device without an expensive display panel) can be equipped with the contact actuator and air mass actuator to allow the device to be used as an inexpensive but effective user equipment.

A second set of embodiments which enhance the audio performance of the contact transducer (and the conventional transducer) is to provide micro-holes in the display or surface. These micro-holes can be arranged in any suitable number, arrangement, or array and operate as almost invisible to the eye acoustic windows permitting the frequency components of the audio signal to be reproduced by passing through the display or surface via the micro-holes. In such embodiments the contact (and conventional) transducer generates sound waves which are radiated to the exterior of the apparatus via these micro-holes in order to produce a suitable acoustic performance.

The micro-holes can be considered to form a porous region of the surface, display or display window and may be determined based on desired acoustic and/or mechanical characteristics. For example, the micro-holes may comprise a diameter which ranges from 0.02 mm up to 0.5 mm. In some embodiments, the one or more porous regions may have characteristics that are selected to provide a determined acoustic response. In some embodiments, the selected porous region characteristics may include one or more of diameter, area, pitch, thickness, pitch/diameter ratio, porous area, total open area or relative open area.

In these embodiments described herein an acoustic or sound signal and a further acoustic or sound signal are featured. It would be understood that in some embodiments the signals are based on the same origin signal. For example a voice audio signal which is reproduced by the apparatus as an acoustic or sound signal (representing or reproducing a first set of frequency components of the audio signal) and a further acoustic or sound signal (representing or reproducing a first set of frequency components of the audio signal).

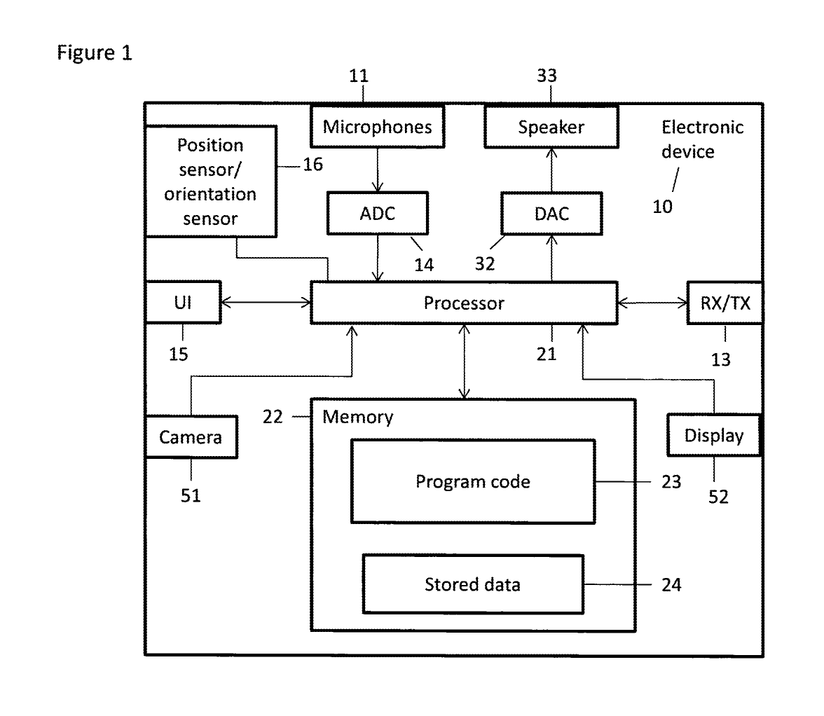

In this regard reference is first made to FIG. 1 which shows a schematic block diagram of an exemplary apparatus or electronic device 10, which may be used as for example as a host or a remote device.

The electronic device 10 may for example be a mobile terminal or user equipment of a wireless communication system when functioning as the recording apparatus or listening apparatus. In some embodiments the apparatus can be an audio player or audio recorder, such as an MP3 player, a media recorder/player (also known as an MP4 player), or any suitable portable apparatus suitable for recording audio or audio/video camcorder/memory audio or video recorder.

The apparatus 10 can in some embodiments comprise an audio-video subsystem. The audio-video subsystem for example can comprise in some embodiments a microphone or array of microphones 11 for audio signal capture. In some embodiments the microphone or array of microphones can be a solid state microphone, in other words capable of capturing audio signals and outputting a suitable digital format signal. In some other embodiments the microphone or array of microphones 11 can comprise any suitable microphone or audio capture means, for example a condenser microphone, capacitor microphone, electrostatic microphone, electret condenser microphone, dynamic microphone, ribbon microphone, carbon microphone, piezoelectric microphone, or micro electrical-mechanical system (MEMS) microphone. In some embodiments the microphone 11 is a digital microphone array, in other words configured to generate a digital signal output (and thus not requiring an analogue-to-digital converter). The microphone 11 or array of microphones can in some embodiments output the audio captured signal to an analogue-to-digital converter (ADC) 14.

In some embodiments the apparatus can further comprise an analogue-to-digital converter (ADC) 14 configured to receive the analogue captured audio signal from the microphones and outputting the audio captured signal in a suitable digital form. The analogue-to-digital converter 14 can be any suitable analogue-to-digital conversion or processing means. In some embodiments the microphones are ‘integrated’ microphones containing both audio signal generating and analogue-to-digital conversion capability.

In some embodiments the apparatus 10 audio-video subsystem further comprises a digital-to-analogue converter 32 for converting digital audio signals from a processor 21 to a suitable analogue format. The digital-to-analogue converter (DAC) or signal processing means 32 can in some embodiments be any suitable DAC technology.

Furthermore the audio-video subsystem can comprise in some embodiments a speaker 33. The speaker 33 can in some embodiments receive the output from the digital-to-analogue converter 32 and present the analogue audio signal to the user. In some embodiments the speaker 33 can be representative of multi-speaker arrangement, a headset, for example a set of headphones, or cordless headphones. In the following examples the speaker 33 can comprise both a contact vibration actuator (such as for example a vibra or piezo-electric actuator) coupled either directly or indirectly to the display), and an air vibration transducer (such as a moving coil or moving magnet or integrated hands free transducer) configured to actuate an air mass of which the pressure wave causes the vibration of the display.

In some embodiments the apparatus audio-video subsystem comprises a camera 51 or image capturing means configured to supply to the processor 21 image data. In some embodiments the camera can be configured to supply multiple images over time to provide a video stream.

In some embodiments the apparatus audio-video subsystem comprises a display 52. The display or image display means can be configured to output visual images which can be viewed by the user of the apparatus. In some embodiments the display can be a touch screen display suitable for supplying input data to the apparatus. The display can be any suitable display technology, for example the display can be implemented by a flat panel comprising cells of LCD, LED, OLED, or ‘plasma’ display implementations.

Although the apparatus 10 is shown having both audio/video capture and audio/video presentation components, it would be understood that in some embodiments the apparatus 10 can comprise one or the other of the audio capture and audio presentation parts of the audio subsystem such that in some embodiments of the apparatus the microphone (for audio capture) or the speaker (for audio presentation) are present. Similarly in some embodiments the apparatus 10 can comprise one or the other of the video capture and video presentation parts of the video subsystem such that in some embodiments the camera 51 (for video capture) or the display 52 (for video presentation) is present.

Furthermore although in the following examples it is described that the microphone(s) are part of the apparatus it would be understood that in some embodiments the microphone or microphone array is physically separate from the apparatus. For example the microphone(s) can be located on a headset or hearing aid (where optionally the headset can have an associated video camera or other suitable sensor) which wirelessly or otherwise passes the audio signals and other sensor information to the apparatus for processing.

In some embodiments the apparatus 10 comprises a processor 21. The processor 21 is coupled to the audio-video subsystem and specifically in some examples the analogue-to-digital converter 14 for receiving digital signals representing audio signals from the microphone 11, the digital-to-analogue converter (DAC) 12 configured to output processed digital audio signals, the camera 51 for receiving digital signals representing video signals, and the display 52 configured to output processed digital video signals from the processor 21.

The processor 21 can be configured to execute various program codes. The implemented program codes can comprise for example audio presentation routines such as determining suitable actuator and transducer audio signals to be passed to the contact and air vibration transducers. In some embodiments the program codes can be configured to perform audio signal processing to generate suitable transducer audio signals.

In some embodiments the apparatus further comprises a memory 22. In some embodiments the processor is coupled to memory 22. The memory can be any suitable storage means. In some embodiments the memory 22 comprises a program code section 23 for storing program codes implementable upon the processor 21. Furthermore in some embodiments the memory 22 can further comprise a stored data section 24 for storing data, for example data that has been processed in accordance with the application or data to be processed via the application embodiments as described later. The implemented program code stored within the program code section 23, and the data stored within the stored data section 24 can be retrieved by the processor 21 whenever needed via the memory-processor coupling.

In some further embodiments the apparatus 10 can comprise a user interface 15. The user interface 15 can be coupled in some embodiments to the processor 21. In some embodiments the processor can control the operation of the user interface and receive inputs from the user interface 15. In some embodiments the user interface 15 can enable a user to input commands to the electronic device or apparatus 10, for example via a keypad, and/or to obtain information from the apparatus 10, for example via a display which is part of the user interface 15. The user interface 15 can in some embodiments as described herein comprise a touch screen or touch interface capable of both enabling information to be entered to the apparatus 10 and further displaying information to the user of the apparatus 10.

In some embodiments the apparatus further comprises a transceiver 13, the transceiver in such embodiments can be coupled to the processor and configured to enable a communication with other apparatus or electronic devices, for example via a wireless communications network. The transceiver 13 or any suitable transceiver or transmitter and/or receiver means can in some embodiments be configured to communicate with other electronic devices or apparatus via a wire or wired coupling.

The transceiver 13 can communicate with further apparatus by any suitable known communications protocol, for example in some embodiments the transceiver 13 or transceiver means can use a suitable universal mobile telecommunications system (UMTS) protocol, a wireless local area network (WLAN) protocol such as for example IEEE 802.X, a suitable short-range radio frequency communication protocol such as Bluetooth, or infrared data communication pathway (IRDA).

In some embodiments the apparatus comprises a position sensor 16 configured to estimate the position of the apparatus 10. The position sensor 16 can in some embodiments be a satellite positioning sensor such as a GPS (Global Positioning System), GLONASS or Galileo receiver.

In some embodiments the positioning sensor can be a cellular ID system or an assisted GPS system.

In some embodiments the apparatus 10 further comprises a direction or orientation sensor. The orientation/direction sensor can in some embodiments be an electronic compass, accelerometer, and a gyroscope or be determined by the motion of the apparatus using the positioning estimate.

It is to be understood again that the structure of the electronic device 10 could be supplemented and varied in many ways.

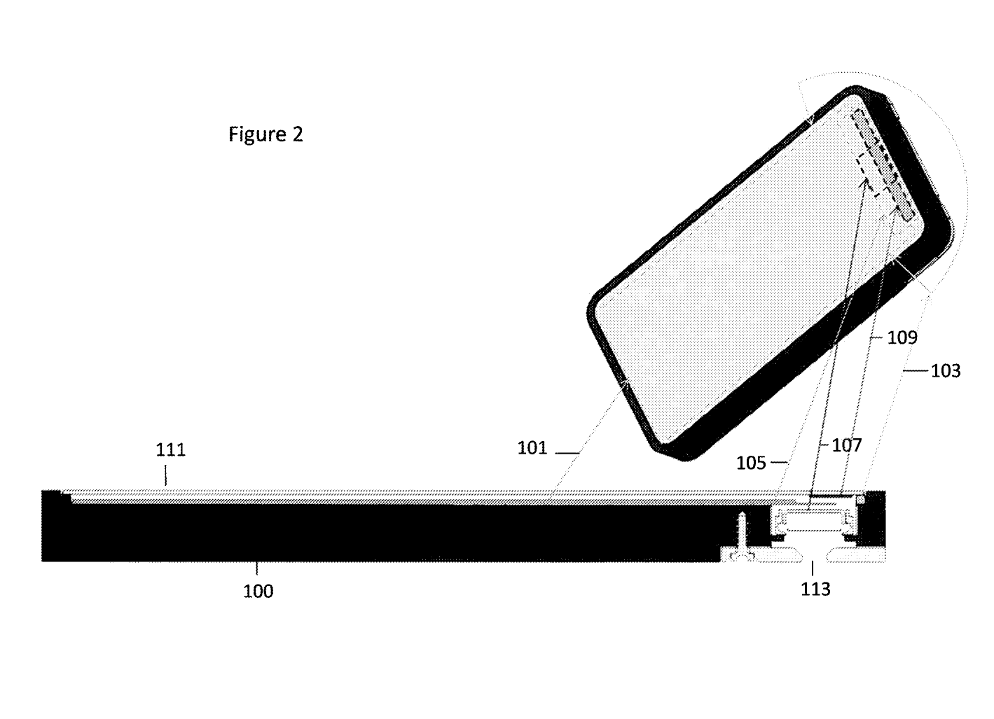

With respect to FIG. 2 an example isometric projection and sectioned elevation of a first apparatus according to some embodiments is shown. The apparatus 100 is shown having a cut out or cavity within which are located other components as described herein. It would be understood that the example shown with respect to FIG. 2 shows components exemplifying some embodiments and as such components which are not directly concerned with the concept are not shown or described in order to simplify and clarify the application. In the example shown in FIG. 2 the apparatus comprises a front window 111 located within a first cut-out or cavity towards the edge or rim of the apparatus 100. In some embodiments the front window 111 is located or supported along at least one side within a first level or height cut-out and supported along at least one further side by a soft fixing or suspension fixing 103 which is configured to permit or enable the front window 111 to move. In such embodiments the soft fixing or suspension fixing can be a rubber or other flexible material which lies in a second level or height cut-out of the apparatus such that the combined height of the second level and the suspension fixing is the height of the first level. In some embodiments the front window 111 is coupled to the apparatus body by a soft fixing or suspension fixing along the whole of the perimeter of the front window 111, but where the front window 111 suspension is heavily damped on some sides to prevent the front window 111 from moving under pressure of the users finger.

In the example shown in FIG. 2 the front window 111 the side which is coupled to the apparatus by the soft or suspension fixing is further configured to be coupled to a contact actuator (or a mechanical or ‘discant’ actuator) mounted directly to the display window. The contact actuator (or contact transducer) in some embodiments is a piezo-electric actuator 109 configured to cause the front window 111 to vibrate as a response to the bending motion of the actuator. However it would be understood that the contact actuator or ‘discant’ actuator can be any suitable kind of actuator, for example a voice coil motor, a vibra or otherwise. Furthermore it would be understood that in some embodiments the contact actuator is coupled to the front window 111 via a flexible pad or strip to dampen the actuation of the front window 111.

In some embodiments the apparatus further comprises a display 101 (or display module). In some embodiments such as shown in the example shown in FIG. 2 the display module 101 is located underneath the front window but is separated from the ‘moving’ or ‘vibrating’ front window 111 by an air gap between the front window 111 and the display module 101. However in some embodiments the display module 101 can be laminated to the front window 111, in other words there is no air gap between the display module 101 and the front window 111 and both the display module 101 and the front window 111 move or vibrate together. In such embodiments the apparatus comprises an air gap formed beneath the display module within the apparatus cavity.

In some embodiments the display module area 101 could be located underneath the piezo electric component such as shown in FIG. 2 so to limit the size of the ‘dead’ band′ where no image is displayed and/or no touch input is detected.

In some embodiments the apparatus further comprises a further transducer or actuator. The further transducer or actuator can be any suitable transducer or actuator. For example in some embodiments the transducer or actuator is a conventional (such as multifunction device vibra) transducer. In the following examples described herein the further transducer or actuator is an air mass actuator located also within the apparatus cavity. The air mass actuator (or transducer) in some embodiments comprises an integrated hands free (IHF) speaker 107. The integrated hands-free speaker 107 in some embodiments is configured such the front cavity or volume of the transducer produces sound or acoustic waves which pass through the rear face of the apparatus rear face via the audio outlet 113 and that the back cavity or rear cavity 105 of the speaker includes the volume of air within the air gap between the front window 111 and the display module 101 (or the combined front glass and display module 101 and the apparatus body). Furthermore in some embodiments the air mass actuator, for example the integrated hands free speaker, is located approximately ‘underneath’ the contact actuator. In such embodiments both the contact actuator and the air mass actuator are located towards one of the short sides of the apparatus approximately in the region which would contain an earpiece transducer in a conventional mobile device so that when the apparatus was in use and the user held the apparatus to the user's ear the vibrations are configured to be more strongly felt at that location. Although in some embodiments the audio outlet 113 is located on the rear face of the apparatus it would be understood that in some embodiments the integrated hands-free speaker audio outlet or opening can be located anywhere on the body of the apparatus, such as for example along the edge(s) of the apparatus.

Thus the apparatus is configured to drive both the contact, piezo-electric transducer, and the air mass (the integrated hands free speaker) actuators or transducers such that the apparatus front window 111 is directly vibrated using the contact actuator in order to provide higher frequency components whereas the apparatus front window 111 is indirectly vibrated via the pressure waves (acoustic waves) generated by the air mass transducer to vibrate the front window 111 to produce lower frequency components of the audio output in a forward or front direction.

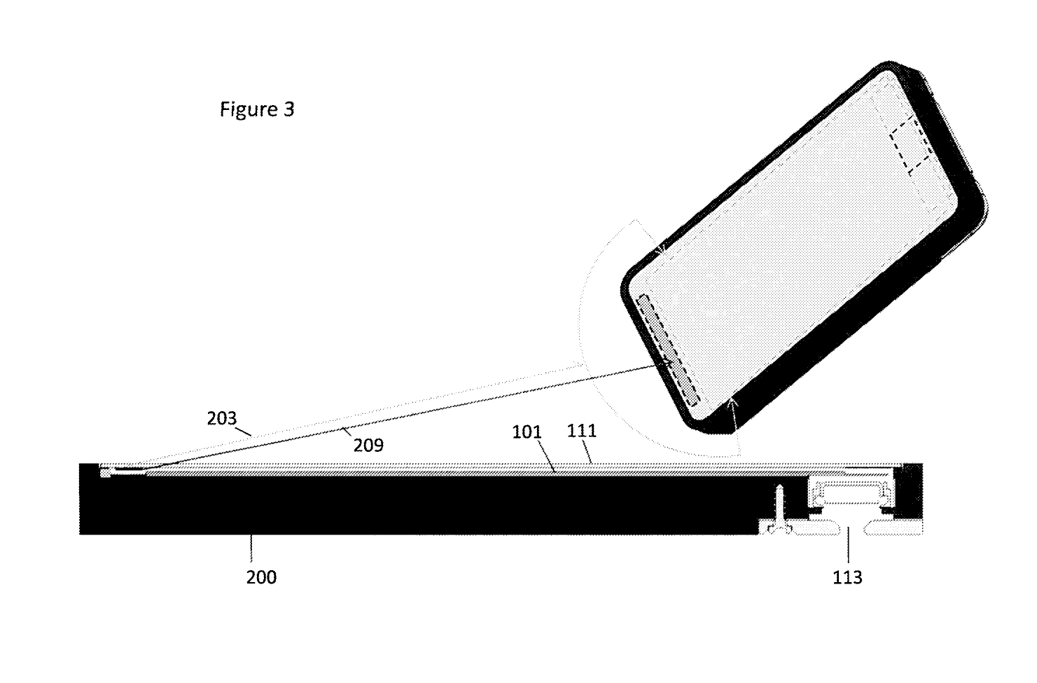

With respect to FIG. 3 an example isometric projection and sectioned elevation of a second apparatus according to some embodiments is shown. The apparatus 200 is shown having a cut out or cavity within which are located other components as described herein. It would be understood that the example shown with respect to FIG. 3 shows components exemplifying some embodiments and as such components which are not directly concerned with the concept are not shown or described in order to simplify and clarify the application. In the example shown in FIG. 3 the apparatus 200 comprises a front window 111 located within a first cut-out or cavity towards the edge or rim of the apparatus 200. In some embodiments the front window 111 is located or supported along at least one side within a first level or height cut-out and supported along at least one further side by a soft fixing or suspension fixing 203 which is configured to permit or enable the front window 111 to move. In such embodiments the soft fixing or suspension fixing can be a rubber or other flexible material which lies in a second level or height cut-out of the apparatus such that the combined height of the second level and the suspension fixing is the height of the first level. In some embodiments the front window 111 is coupled to the apparatus body by a soft fixing or suspension fixing along the whole of the perimeter of the front window 111, but where the front window 111 suspension is heavily damped on some sides to prevent the front window 111 from moving under pressure of the users finger.

In the example shown in FIG. 3 the front window 111 the side which is coupled to the apparatus by the soft or suspension fixing is further configured to be coupled to a contact actuator (or a mechanical or ‘discant’ actuator) mounted directly to the window. The contact actuator (or contact transducer) in some embodiments is a piezo-electric actuator 209 configured to cause the front window 111 to vibrate as a response to the bending motion of the actuator. However it would be understood that the contact actuator or ‘discant’ actuator can be any suitable kind of actuator, for example a voice coil motor, a vibra or otherwise. Furthermore it would be understood that in some embodiments the contact actuator is coupled to the front window 111 via a flexible pad or strip to dampen the actuation of the front window 111.

In some embodiments the apparatus further comprises a display 101 (or display module). In some embodiments such as shown in the example shown in FIG. 3 the display module 101 is located underneath the front window but is separated from the ‘moving’ or ‘vibrating’ front window 111 by an air gap between the front window 111 and the display module 101. However in some embodiments the display module 101 can be laminated to the front window 111, in other words there is no air gap between the display module 101 and the front window 111 and both the display module 101 and the front window 111 move or vibrate together. In such embodiments the apparatus comprises an air gap formed beneath the display module within the apparatus cavity.

In some embodiments the apparatus further comprises an air mass actuator located also within the apparatus cavity. The air mass actuator (or transducer) in some embodiments comprises an integrated hands free (IHF) speaker. The integrated hands-free speaker in some embodiments is configured such the front cavity or volume of the transducer produces sound or acoustic waves which pass through the rear face of the apparatus rear face via the audio outlet 113 and that the back cavity or rear cavity of the speaker includes the volume of air within the air gap between the front window 111 and the display module 101 (or the combined front glass and display module 101 and the apparatus body). Furthermore in some embodiments such as shown in FIG. 3, the air mass actuator, for example the integrated hands free speaker, is located at the opposite edge and ‘underneath’ the contact actuator. Although in some embodiments the audio outlet 113 is located on the rear face of the apparatus it would be understood in a manner similar to that described herein that in some embodiments the integrated hands-free speaker audio outlet or opening can be located anywhere on the body of the apparatus, such as for example along the edge(s) of the apparatus. In such an arrangement as shown in FIG. 3 the IHF speaker box can be located at the bottom end of the device in a volume which comprises the cellular antenna. There is furthermore located a small airgap behind the display which can transfer the low frequencies from the IHF. At the top end (the conventional earpiece location) there is located the contact actuator or transducer for high frequency component generation.

Thus the apparatus is configured to drive both the contact, piezo-electric actuator or transducer, and the conventional, such as air mass (the integrated hands free speaker), actuators or transducers such that the apparatus front window 111 is vibrated using the contact actuator in order to provide higher frequency components whereas the apparatus front window 111 is vibrated via the pressure waves (acoustic waves) generated by the air mass transducer to vibrate the front window 111 to produce lower frequency components of the audio output in a forward or front direction. The lower frequency or bass waves in the example apparatus shown in FIG. 3 can travel under the front window 111 to the other end and so the relative alignment of the contact actuator and the air mass actuator is not required and the air mass actuator can be located at any other suitable location within the apparatus cavity.

It would be understood that in some embodiments there can be implemented more than one contact actuator (piezoelectric transducer) and/or more than one air mass actuator (integrated hands free speaker).

For example the front window on the side which is coupled to the apparatus by the soft or suspension fixing can be further configured to be coupled to a first contact actuator (or a mechanical or ‘discant’ actuator) mounted directly to the window. The contact actuator (or contact transducer) in some embodiments is a piezo-electric actuator configured to cause the front window to vibrate as a response to the bending motion of the actuator. Furthermore in some embodiments the front window on the side which is coupled to the apparatus by a further soft or suspension fixing is further configured to be coupled to a further contact actuator or a ‘discant’ actuator mounted directly to the window. The further contact actuator (or contact transducer) in some embodiments is a second or further piezo-electric actuator configured to cause the front window to vibrate as a response to the bending motion of the actuator on the short side opposite to the short side vibrated by the first contact actuator. In some embodiments the apparatus further comprises an air mass actuator located also within the apparatus cavity. The air mass actuator (or transducer) in some embodiments comprises an integrated hands free (IHF) speaker. The integrated hands-free speaker in some embodiments is configured such the front cavity or volume of the transducer produces sound or acoustic waves which pass through the rear face of the apparatus rear face via the audio outlet and that the back cavity or rear cavity of the speaker includes the volume of air within the air gap between the front window and the display module 101 (or the combined front glass and display module and the apparatus body). Furthermore in some embodiments the air mass actuator, for example the integrated hands free speaker, is located approximately ‘underneath’ the first contact actuator. In such embodiments both the first contact actuator and the air mass actuator are located towards one of the short sides of the apparatus approximately in the region which would contain an earpiece transducer in a conventional mobile device so that when the apparatus was in use and the user held the apparatus to the user's ear the vibrations are configured to be more strongly felt at that location. Furthermore the air mass actuator is located at the opposite edge and ‘underneath’ the further or second contact actuator. In other words the apparatus can be considered to be a combination of the apparatus shown in FIGS. 2 and 3 with respect to the location of the first and further piezo-electric actuators or transducers, effectively having a top end and bottom end contact actuators or contact transducers. As described herein the relative positioning of the contact and air mass actuators are such that the further contact actuator and the air mass actuator can combine to create a ‘second effective earpiece’ area and would thus enable the apparatus to be operated ‘either way up’.

Although in some embodiments the audio outlet 113 is located on the rear face of the apparatus it would be understood in a manner similar to that described herein that in some embodiments the integrated hands-free speaker audio outlet or opening can be located anywhere on the body of the apparatus, such as for example along the edge(s) of the apparatus.

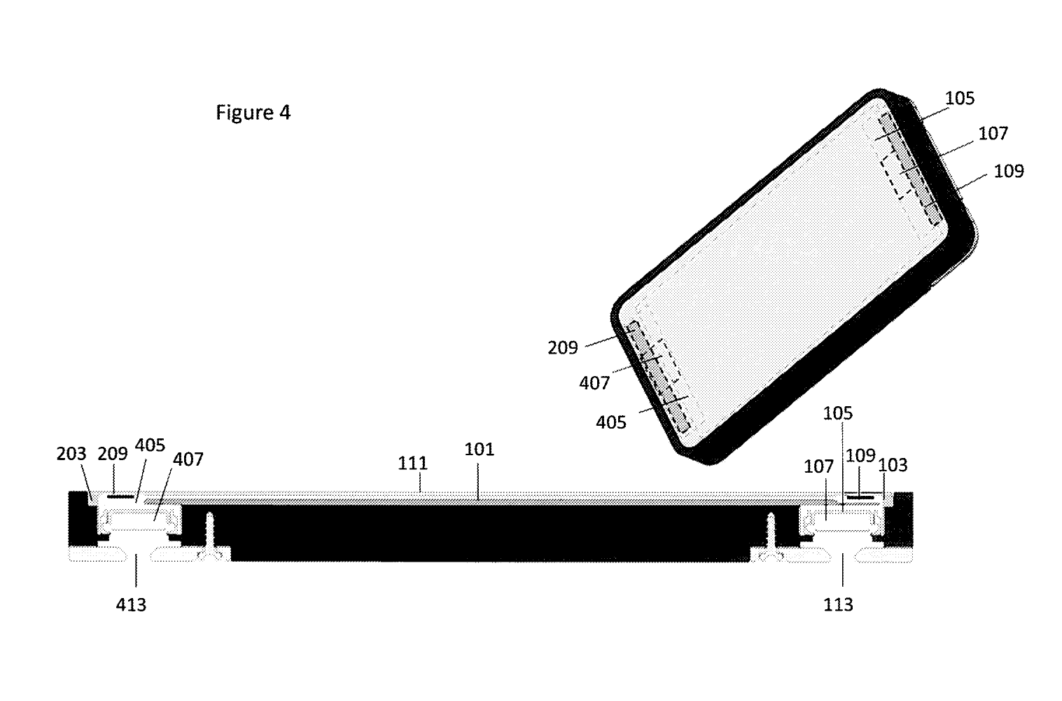

With respect to FIG. 4 an example isometric projection and sectioned elevation of a further multiple contact actuator apparatus according to some embodiments is shown. The apparatus 400 is shown having a cut out or cavity within which are located other components as described herein. It would be understood that the example shown with respect to FIG. 4 shows components exemplifying some embodiments and as such components which are not directly concerned with the concept are not shown or described in order to simplify and clarify the application. In the example shown in FIG. 4 the apparatus 400 comprises a front window 111 located within a first cut-out or cavity towards the edge or rim of the apparatus 400. In some embodiments the front window 111 is located or supported along at least one side by a soft fixing or suspension fixing 103 which is configured to permit or enable the front window 111 to move. Furthermore the front window 111 is located or supported along the other short side by a further soft fixing or suspension fixing 203. In some embodiments the front window 111 is coupled to the apparatus body by a soft fixing or suspension fixing along the whole of the perimeter of the front window 111, but where the front window 111 suspension is heavily damped on some sides to prevent the front window 111 from moving under pressure of the users finger.

In the example shown in FIG. 4 the front window 111 on the side which is coupled to the apparatus by the soft or suspension fixing is further configured to be coupled to a first contact actuator (or a mechanical or ‘discant’ actuator) mounted or mechanically coupled to the window. The contact actuator (or contact transducer) in some embodiments is a piezo-electric actuator 109 configured to cause the front window 111 to vibrate as a response to the bending motion of the actuator. Furthermore in some embodiments the front window 111 on the side which is coupled to the apparatus by the further soft or suspension fixing is further configured to be coupled to a further contact actuator (or a mechanical or ‘discant’ actuator) mounted or mechanically coupled to the window. The further contact actuator (or contact transducer) in some embodiments is a second or further piezo-electric actuator 209 configured to cause the front window 111 to vibrate as a response to the bending motion of the actuator on the short side opposite to the short side vibrated by the first contact actuator.

It would be understood that in a manner as described herein the contact actuator or ‘discant’ actuator can be any suitable kind of actuator, for example a voice coil motor, a vibra or otherwise. Furthermore it would be understood that in some embodiments the further and further contact actuators can be mechanically coupled to the front window 111 via a flexible pad or strip to dampen the actuation of the front window 111.

In some embodiments the apparatus further comprises a display 101 (or display module). In some embodiments such as shown in the example shown in FIG. 3 the display module 101 is located underneath the front window but is separated from the ‘moving’ or ‘vibrating’ front window 111 by an air gap between the front window 111 and the display module 101. However in some embodiments the display module 101 can be laminated to the front window 111, in other words there is no air gap between the display module 101 and the front window 111 and both the display module 101 and the front window 111 move or vibrate together. In such embodiments the apparatus comprises an air gap formed beneath the display module within the apparatus cavity.

In some embodiments the apparatus further comprises a first air mass actuator located also within the apparatus cavity. The first air mass actuator (or transducer) in some embodiments comprises a first integrated hands free (IHF) speaker 107. The integrated hands-free speaker in some embodiments is configured such the front cavity or volume of the transducer produces sound or acoustic waves which pass through the rear face of the apparatus rear face via the audio outlet 113 and that the back cavity or rear cavity 105 of the speaker includes the volume of air within the air gap between the front window 111 and the display module 101 (or the combined front glass and display module 101 and the apparatus body). Furthermore in some embodiments such as shown in FIG. 4, the air mass actuator, for example the integrated hands free speaker, is located approximately ‘underneath’ the first contact actuator. In such embodiments both the first contact actuator and the air mass actuator are located towards one of the short sides of the apparatus approximately in the region which would contain an earpiece transducer in a conventional mobile device so that when the apparatus was in use and the user held the apparatus to the user's ear the vibrations are configured to be more strongly felt at that location.

In some embodiments the apparatus further comprises a second or further air mass actuator located also within the apparatus cavity. The first air mass actuator (or transducer) in some embodiments comprises a second or further integrated hands free (IHF) speaker 407. The further integrated hands-free speaker 407 in some embodiments is configured such the front cavity or volume of the transducer produces sound or acoustic waves which pass through the rear face of the apparatus rear face via a further audio outlet 413 and that the back cavity or rear cavity 405 of the speaker includes the volume of air within the air gap between the front window 111 and the display module 101 (or the combined front glass and display module 101 and the apparatus body). Furthermore in some embodiments such as shown in FIG. 4, the air mass actuator, for example the second or further integrated hands free speaker, is located approximately ‘underneath’ the second contact actuator. In such embodiments both the second contact actuator and the second air mass actuator are located towards the opposite one of the short sides of the apparatus to the co-location of the first contact actuator and the first air mass actuator and approximately in the region which would contain an earpiece transducer in a conventional mobile device where the apparatus was in use in an opposite orientation to that described with respect to the first contact actuator and first air mass actuator orientation. As described herein the relative positioning of the contact and air mass actuators are such that the second contact actuator and the second air mass actuator can combine to create a ‘second effective earpiece’ area and would thus enable the apparatus to be operated ‘either way up’ and further support stereo integrated hands free speaker operation.

Although in some embodiments the audio outlet 113 is located on the rear face of the apparatus it would be understood in a manner similar to that described herein that in some embodiments the integrated hands-free speaker audio outlet or opening can be located anywhere on the body of the apparatus, such as for example along the edge(s) of the apparatus.

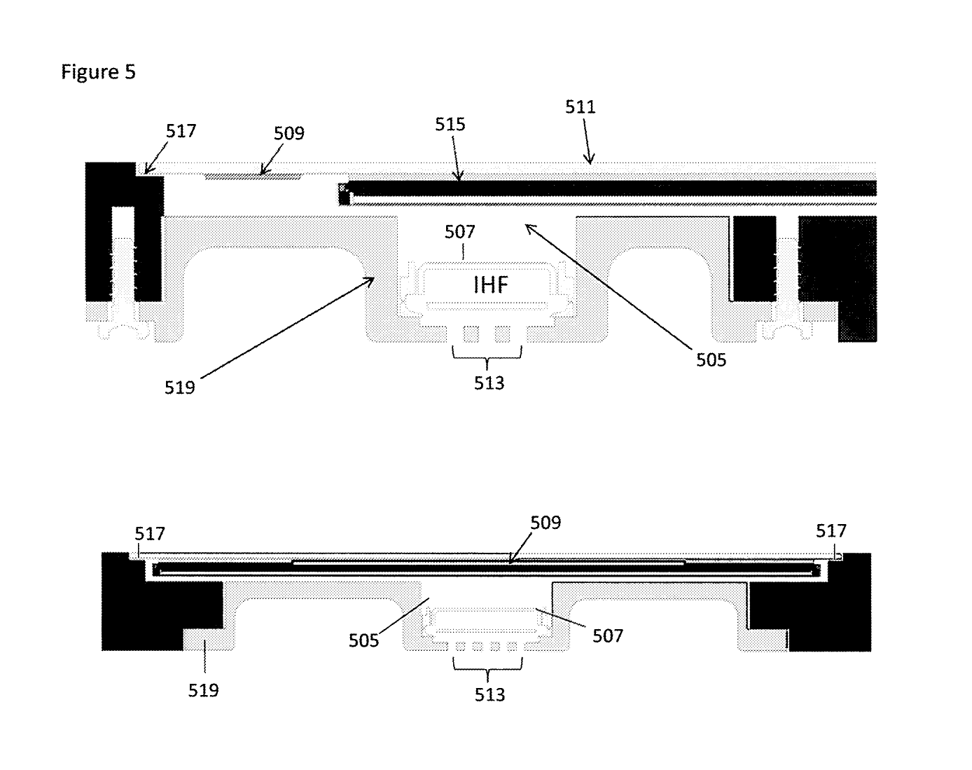

In some embodiments the air mass actuator, such as the integrated hands free transducer is configured to be located with respect to the apparatus within a sub-assembly of chassis member Furthermore with respect to FIG. 5 two cross-sectional views, a cross-section in the x-direction and a cross-section in the y-direction of such an example apparatus are further shown. In the example shown in FIG. 5 the location of the air mass actuator, the integrated hands-free (IHF) speaker 507 is fixed or located within the apparatus by a locating sub-assembly member or hatch 519 comprising an acoustic outlet 513 permitting the integrated hands-free speaker 507 to generate acoustic waves which exit the apparatus at the rear or back of the apparatus. Furthermore the integrated hands-free speaker 507 is located such that there is a defined back volume 505 which continues under the front window 511 and display (stack) 515. In the example shown in FIG. 5 the front window 515 and display (stack) 515 are coupled together. Furthermore the front window 511 is fixed or coupled to the apparatus body via a window fixing 517. The window fixing 517 can in some embodiments be a glue or other bonding material or in some embodiments be a flexible, soft or suspension fixing (such as a rubber or foam material) enabling the front window to vibrate without being damped by a rigid fixing to the apparatus.

In the examples shown in FIG. 5 the piezoelectric actuator or transducer 509 operates as the contract actuator in the x-direction as shown in FIG. 5. The piezoelectric actuator or transducer 509 or contact actuator can in some embodiments be glued or bonded to the underside of the front window 511.

It would be understood that in a manner similar to that described herein the location of the integrated hands-free speaker (operating as the air-mass actuator) can be anywhere within the apparatus and the location of the integrated hands-free speaker 507 as shown in FIG. 5 approximately half way across the apparatus in the x-direction and towards one of the ends in the y-direction is an example location only. Furthermore as described herein the location of the output port to the rear of the apparatus is an example only.

In some embodiments the locating sub-assembly member (which supports the integrated hands free speaker) as shown in FIG. 5 is shown having a recess region. However the locating sub-assembly member is an example only and it would be understood that the locating sub-assembly member for locating the integrated hands-free speaker within the apparatus can be any suitable shape or configuration.

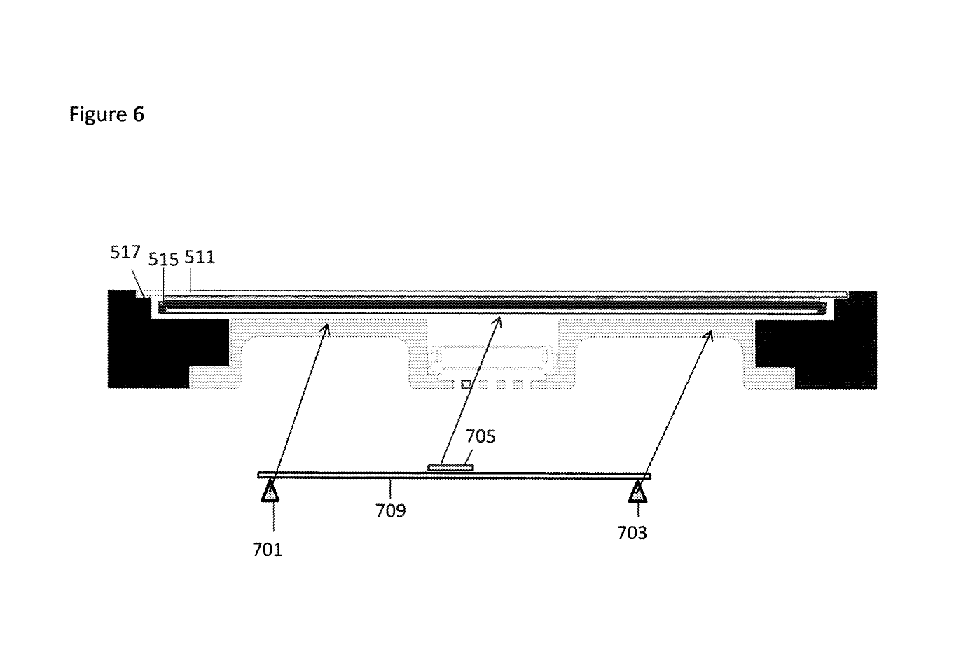

With respect to FIG. 6 a further example of the contact transducer or actuator is shown wherein in some embodiments the contact transducer or actuator, the piezoelectric actuator or transducer 709 can in some embodiments be configured such that piezoelectric actuator or transducer (or bending beam) is used as a solid actuator such that the ends of the beam shown as points 701 and 703 are connected to a non-moving support, for example with respect to the example apparatus as shown in FIG. 6 the non-moving support can be the hatch which locates the integrated hands-free speaker and the piezoelectric actuator or transducer 709. The piezoelectric actuator or transducer furthermore is configured with a contact point or pad 705 which is coupled to the front window 511 to transmit the motion of the piezoelectric transducer to the front window 511.

The size of the piezoelectric actuator or transducer used in embodiments can be such that an eight layer piezoelectric actuator or transducer can be used with approximate dimensions of 6 mm×50 mm×0.3 mm. However these are example dimensions and it would be understood that the piezoelectric actuator or transducer can be any suitable size and configuration. Furthermore for example if the piezoelectric actuator or transducer is implemented as a solid driving component (in other words the ends connected to a chassis and the centre to a window component) then the size could be for example 2.4 mm×20 mm×0.8 mm. It would be understood that solid driving is more efficient, and components can have smaller foot prints (in other words require less piezoelectric material) at the expense of thickness (because a carrier+some air gap has to be added). If the piezoelectric actuator or transducer ceramic is attached straight to glass, then the construction is the thinnest possible.

In some embodiments the contact actuator (such as the piezoelectric actuator or transducer) and air mass actuator (such as the integrated hands free speaker) are controlled based on the audio signal being replayed and the mode of operation of the output.

Thus for example the processor or amplifier can be configured to operate in a first mode, an earpiece mode, where a band division filter is configured to separate the frequencies to be output such that a lower frequency range audio component is passed to the air mass actuator and the higher frequency range audio component is passed to the contact actuator or transducer. In some embodiments the band division filter can comprise a low pass and high pass filter configured to receive the audio signal to be replayed and the high pass filter is configured to output to the contact actuator and the low pass filter is configured to output to the air-mass actuator. An example frequency division range can be 100 to 500 Hz audio signals being passed to the integrated hands-free speaker (air-mass actuator) whereas audio signals with higher frequencies (>500 Hz) are passed to the piezo-electric actuator or transducer (contact actuator).

Furthermore in a second mode of operation, an integrated hands free mode, then the audio signal is passed directly to the air-mass actuator for example the integrated hands-free speaker only.

In this manner the piezo-electric actuators or transducers mounted on the front window can produce the higher frequency component and the integrated hands-free speaker generate pressure waves which transfer the lower frequency components to the front window and to the users ear.

Furthermore in some embodiments the processor can be configured to select one piezoelectric actuator or transducer from more than one piezoelectric actuator or transducer to select one of the alternative earpiece locations when the apparatus is functioning in earpiece mode. Thus for example in the apparatus shown in FIG. 4 where there are two piezoelectric actuators or transducers then one or other of the piezoelectric actuators or transducers is selected. This selection can be based on any suitable method such as position, for example the highest or uppermost of the transducers being selected or the orientation of the apparatus determining the selection, or by a determination of a contact surface such as the ear placed on the apparatus (for example a detection using the capacitive effect of the touch screen) or other proximity sensor.

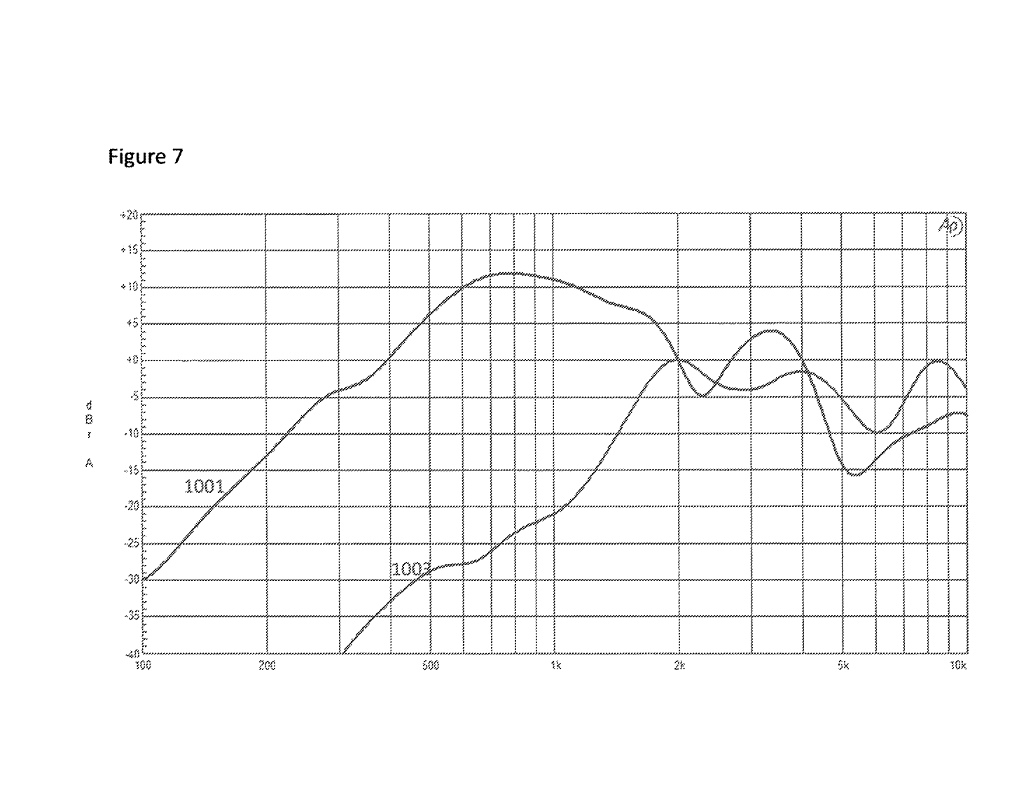

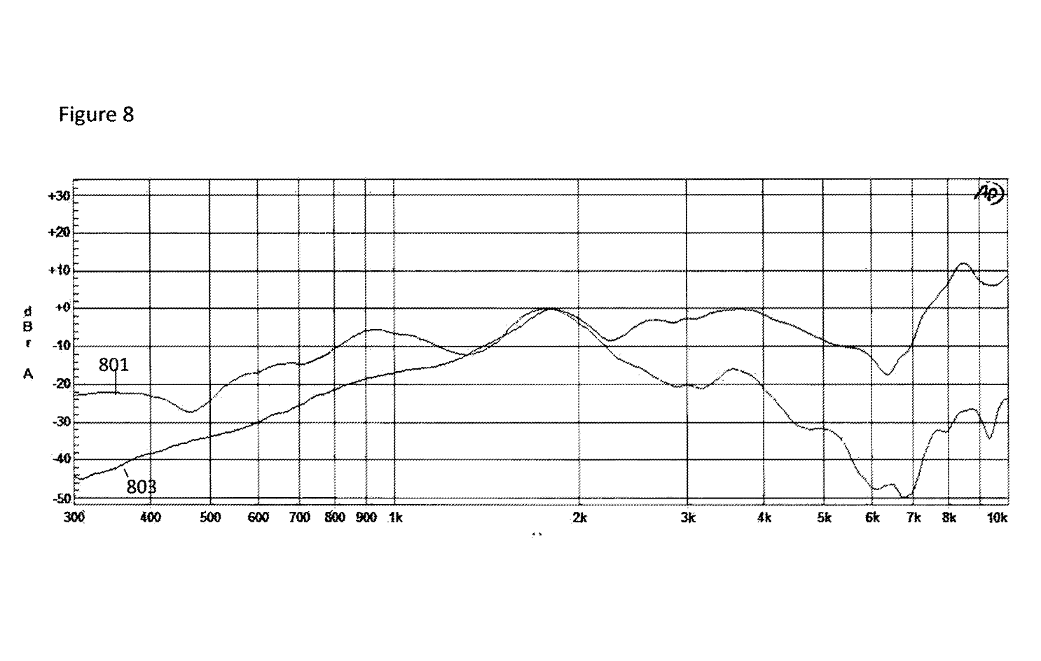

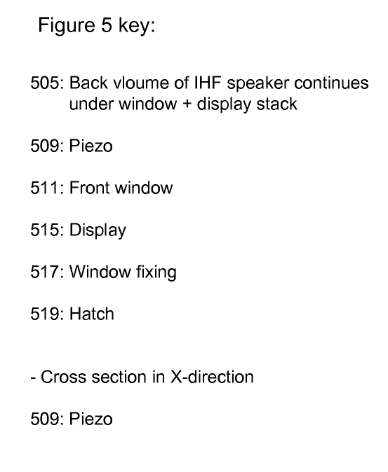

With respect to FIGS. 7 and 8 example frequency response traces are shown showing examples apparatus as described herein. For example FIG. 7 shows example audio frequency response measurements for an example implementation such as shown in FIG. 2, wherein the contact actuator or piezoelectric actuator or transducer and the air mass actuator or integrated hands free speaker are located at the same end of the apparatus and the ‘ear’ from which the measurements are made is located in contact with the apparatus surface on the opposite side from the contact actuator. In FIG. 8 the trace 1001 shows the air mass actuator or integrated hands-free speaker response as measured through the front window. Here it can be seen that the frequency response for the integrated hands-free speaker response is good for lower frequency components but is poor for higher frequency components above for example 2 kHz. The trace 1003 shows the frequency response for the contact actuator or piezoelectric actuator or transducer. The frequency response trace 1003 for the contact actuator or piezoelectric transducer shows that the frequency response for low frequencies below 2 kHz is poor but the frequency response for frequencies above 2 kHz is much better than the integrated hands-free speaker response measured through the front window. In other words the integrated hands-free speaker can effectively support the output of low frequency components generated by the piezoelectric actuator or transducer and vice versa for the high frequency components and the integrated hands free speaker. In the example represented by the traces 1001 and 1003 it would be understood that the filtering of the audio components to be output by the display could have a frequency band division at about 2 kHz, in other words the audio circuitry driving the transducers can comprise a band pass filter with a pass band located below 2 kHz for the integrated hands free speaker and a pass band located above 2 kHz for the piezoelectric actuator or transducer.

With respect to FIG. 8 a further example of the frequency response traced with respect to embodiments as described herein is shown. In this Figure the measurements have been made with respect to an example implementation wherein the contact actuator or piezoelectric actuator or transducer is located at one end of the apparatus and the air mass actuator or integrated hands free speaker are located at the opposite end of the apparatus, with the ‘ear’ from which the measurements are made is located in contact with the apparatus surface on the opposite side from the contact actuator.

In this example the first trace 801 shows the opposite end located integrated hands free speaker response and the second trace 803 shows the contact actuator response. From these traces it can be seen, as described herein, that the location of the air mass actuator can be flexibly placed relative to the contact actuator.

In some embodiments the apparatus comprises the contact transducer. For example in some embodiments the contact transducer is a piezoelectric actuator or transducer. In such embodiments the display or surface is configured such that it comprises at least one porous region comprising one or more micro-hole located ‘over’ the contact actuator or transducer region. The at least one micro-hole can for example be formed by a laser drill to form a hole in the region of 0.02 mm to 0.5 mm in diameter. It would be understood that the number, configuration and arrangement of such micro-holes can be in any suitable number, arrangement. These micro-holes are almost invisible to the eye but are configured to operate as acoustic windows permitting the sound waves to be radiated by passing through the display or surface via the micro-holes. In such a manner the contact transducer can be configured to produce an enhanced audio or acoustic response.

It shall be appreciated that the term portable device is user equipment. The user equipment is intended to cover any suitable type of wireless user equipment, such as mobile telephones, portable data processing devices or portable web browsers.

In general, the various embodiments may be implemented in hardware or special purpose circuits, software, logic or any combination thereof. Some aspects of the invention may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

The embodiments of this invention may be implemented by computer software executable by a data processor of the mobile device, such as in the processor entity, or by hardware, or by a combination of software and hardware.

For example, in some embodiments the method of manufacturing the apparatus may be implemented with processor executing a computer program.

Further in this regard it should be noted that any blocks of the logic flow as in the Figures may represent program steps, or interconnected logic circuits, blocks and functions, or a combination of program steps and logic circuits, blocks and functions. The software may be stored on such physical media as memory chips, or memory blocks implemented within the processor, magnetic media such as hard disk or floppy disks, and optical media such as for example DVD and the data variants thereof, CD.

The memory may be of any type suitable to the local technical environment and may be implemented using any suitable data storage technology, such as semiconductor-based memory devices, magnetic memory devices and systems, optical memory devices and systems, fixed memory and removable memory. The data processors may be of any type suitable to the local technical environment, and may include one or more of general purpose computers, special purpose computers, microprocessors, digital signal processors (DSPs), application specific integrated circuits (ASIC), gate level circuits and processors based on multi-core processor architecture, as non-limiting examples.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

As used in this application, the term ‘circuitry’ refers to all of the following:

(a) hardware-only circuit implementations (such as implementations in only analog and/or digital circuitry) and

(b) to combinations of circuits and software (and/or firmware), such as: (i) to a combination of processor(s) or (ii) to portions of processor(s)/software (including digital signal processor(s)), software, and memory(ies) that work together to cause an apparatus, such as a mobile phone or server, to perform various functions and

(c) to circuits, such as a microprocessor(s) or a portion of a microprocessor(s), that require software or firmware for operation, even if the software or firmware is not physically present.

This definition of ‘circuitry’ applies to all uses of this term in this application, including any claims. As a further example, as used in this application, the term ‘circuitry’ would also cover an implementation of merely a processor (or multiple processors) or portion of a processor and its (or their) accompanying software and/or firmware. The term ‘circuitry’ would also cover, for example and if applicable to the particular claim element, a baseband integrated circuit or applications processor integrated circuit for a mobile phone or similar integrated circuit in server, a cellular network device, or other network device.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims. Indeed in there is a further embodiment comprising a combination of one or more of any of the other embodiments previously discussed.

1. An apparatus comprising:
a surface;
at least one contact transducer, wherein the at least one contact transducer is coupled to the surface and configured to move the surface to generate at least one acoustic signal, wherein the at least one acoustic signal is configured to be transmitted at least by the surface;
at least one acoustic enhancer configured to enhance the acoustic output of the at least one contact transducer wherein the at least one acoustic enhancer comprises at least one further transducer configured to generate at least one further acoustic signal.

2. The apparatus as claimed in claim 1, wherein the at least one further transducer is configured to generate the at least one further acoustic signal by moving the surface, such that the at least one further acoustic signal enhances the frequency response of the at least one contact transducer.

3. The apparatus as claimed in claim 1, wherein the at least one further transducer is configured to generate the at least one further acoustic signal towards an acoustic volume at least partially defined by one side of the at least one further transducer.

4. The apparatus as claimed in claim 3, wherein the acoustic volume is further defined at least by the surface.

5. The apparatus as claimed in claim 3, further comprising a further acoustic volume at least partially defined by the other side of the at least one further transducer and at least one acoustic port wherein the at least one further transducer is configured to output at least one additional acoustic signal via the further acoustic volume and the at least one acoustic port.

6. The apparatus as claimed in claim 5, wherein the further acoustic volume is further defined at least by a casing of the apparatus.

7. The apparatus as claimed in claim 6, wherein the at least one acoustic port is located within the casing of the apparatus, and wherein the at least one additional acoustic signal is configured to be transmitted from the apparatus by passing through the at least one acoustic port.

8. The apparatus as claimed in claim 1, wherein the at least one further transducer comprises at least one of:
at least one integrated hands free speaker;
at least one moving coil speaker;
at least one multi-function device; and
at least one piezo-electric transducer.

9. The apparatus as claimed in claim 1, wherein the at least one contact transducer comprises at least one of:
at least one piezoelectric actuator coupled to the surface and configured to bend the surface along the length of the coupling to generate the at least one acoustic signal;
at least one piezoelectric actuator coupled at a first region to the surface and coupled at a second region to at least one anchor point and configured to move the surface relative to the anchor point to generate the at least one acoustic signal;
at least one piezoelectric actuator coupled to a pad, the pad coupled to the surface at a first point and the actuator is further coupled to at least one anchor point at a second point and configured to move the surface via the pad relative to the anchor point to generate the at least one acoustic signal;
at least one first piezoelectric actuator coupled to the surface along a first region and at least one further piezoelectric actuator coupled to the surface along a second region, the first and second regions being located approximately at opposite ends of the surface and configured to bend the surface along the length of the coupling to generate the at least one acoustic signal;
at least one first piezoelectric actuator coupled at a first region to a first location of the surface and coupled at a second region to at least one first anchor point and at least one further piezoelectric actuator coupled at a first region to a further location of the surface and coupled at a second region to at least one further anchor point, wherein the first and second piezoelectric actuators are located approximately at opposite ends of the surface and the at least one first piezoelectric actuator and the at least one further piezoelectric actuator is configured to move the surface relative to the first and further anchor point respectively to generate the at least one acoustic signal; and
at least one first piezoelectric actuator coupled to a first pad, the first pad coupled to the surface at a first location and the at least one first piezoelectric actuator is further coupled to at least one anchor point and at least one further piezoelectric actuator coupled to a further pad, the further pad coupled to the surface at a further location, and the at least one further piezoelectric actuator is further coupled to at least one further anchor point, wherein the first location and the further location being approximately at opposite ends of the surface and the at least one first piezoelectric actuator and at least one further piezoelectric actuator being configured to move the surface via the first and further pad respectively to generate the at least one acoustic signal.

10. The apparatus as claimed in claim 1, further comprising:
at least one audio signal generator configured to generate at least one audio signal to be output by the at least one contact transducer and the at least one further transducer;
at least one low pass filter configured to filter the output of the at least one audio signal generator and coupled to the at least one further transducer to generate lower frequency acoustic signals; and
at least one high pass filter configured to filter the output of the at least one audio signal generator and coupled to the at least one contact transducer to generate higher frequency acoustic signals.

11. The apparatus as claimed in claim 10, further comprising at least one audio signal generator configured to generate at least one audio signal to be output by the at least one further transducer only, when the apparatus is operating in a handsfree mode.

12. The apparatus as claimed in claim 1, wherein the at least one acoustic enhancer configured to enhance the acoustic output of the at least one contact transducer comprises:
at least one micro-hole through the surface, wherein the at least one micro-hole is configured to operate as an acoustic window such that the acoustic signal and the further acoustic signal can pass through the acoustic window and enhance the frequency response of the at least one contact transducer.

13. The apparatus as claimed in claim 1, wherein the at least one contact transducer comprises at least one of:
at least one piezoelectric actuator;
at least one vibra; and
at least one actuator configured to move the surface.

14. The apparatus as claimed in claim 1, wherein the surface comprises at least one of:
an apparatus display module;
an apparatus front window; and
an apparatus casing.

15. A method comprising:
providing a surface;
coupling at least one contact transducer to the surface such that the at least one contact transducer moves the surface to generate at least one acoustic signal;
providing at least one acoustic enhancer to enhance the acoustic output of the at least one contact transducer, wherein providing the at least one acoustic enhancer comprises providing at least one further transducer to generate at least one further acoustic signal.

16. The method as claimed in claim 15, wherein providing at least one further transducer further comprising generating the at least one acoustic signal by moving the surface, such that the at least one further acoustic signal enhances the frequency response of the at least one contact transducer.

17. The method as claimed in claim 15, wherein providing at least one acoustic enhancer to enhance the frequency response of the at least one transducer comprises providing at least one micro-hole through the surface, wherein the at least one micro-hole is configured to operate as an acoustic window such that the acoustic signal and further acoustic signal can pass through the acoustic window and enhance the frequency response of the at least one contact transducer.

18. The method as claimed in claim 15, further generating the at least one further acoustic signal towards an acoustic volume at least partially defined by one side of the at least one further transducer.

19. The method as claimed in claim 18, further providing a further acoustic volume at least partially defined by the other side of the at least one further transducer and at least one acoustic port; and outputting at least one additional acoustic signal from the at least one further transducer towards the further acoustic volume and the at least one acoustic port.

20. The method as claimed in claim 19, wherein the further acoustic volume is defined at least by a casing of the apparatus and locating the at least one acoustic port within the casing of the apparatus for transmitting the at least one additional acoustic signal from the apparatus by passing through the at least one acoustic port.
